(19) United States
(12) Patent Application Publication
(10) Pub. No.: US 2026/0134906 A1
(43) Pub. Date: May 14, 2026

(54) FAST LOW-LEAKAGE SRAM CELL

(71) Applicant: OMNIVISION TECHNOLOGIES, INC., Santa Clara, CA (US)

(72) Inventors: Jingjun Yi, San Jose, CA (US); Qing Qin, Sunnyvale, CA (US); Tiejun Dai, Santa Clara, CA (US); Sunny Yat-San Ng, San Jose, CA (US)

(21) Appl. No.: 18/943,781

(22) Filed: Nov. 11, 2024

(51) Int. Cl. G11C 11/412; G11C 11/419

(52) U.S. Cl. CPC G11C 11/412; G11C 11/419

(57) ABSTRACT

Fast low-leakage SRAM cells, such as for digital display systems, are disclosed herein. In one embodiment, a bit storage circuit includes a latch coupled between a supply voltage and ground, and first through fourth transistors. The latch can comprise a pair of cross-coupled inverters having first and second inverters. The first transistor can selectively couple the first inverter to the supply voltage based at least in part on a first control signal. The second transistor can selectively couple an input of the first inverter to ground based at least in part on a second control signal different from the first control signal. The third transistor can selectively couple the second inverter to the supply voltage based at least in part on the second control signal. The fourth transistor can selectively couple an input of the second inverter to ground based at least in part on the first control signal.

### TECHNICAL FIELD

This disclosure relates generally to bit storage devices and associated devices, systems, and methods. For example, several embodiments described in detail below are directed to fast, low-leakage static random-access memory (SRAM) cells, such as for digital displays and/or display pixel circuitry.

### BACKGROUND

SRAM cells are integral components in digital displays, providing a fast and reliable means of storing pixel data. Each SRAM cell typically includes transistors configured to hold a single bit of data and directly control the state of a corresponding pixel. In digital displays such as LCDs and OLEDs, the SRAM cells are used to maintain on or off statuses of individual pixels, ensuring a correct image or video frame is displayed. Unlike dynamic RAM (DRAM), SRAM does not require constant refreshing, making it ideal for applications where quick access to stored data and stability are crucial, particularly in high-performance graphics or real-time image processing.

SRAM cells are valued for their low-latency data retrieval and high speed, enabling displays to render images smoothly and without delay. These characteristics make them a preferred choice for devices requiring quick response times, such as smartphones, tablets, and high-resolution monitors. Their stable storage capabilities help to ensure consistent pixel performance, enhancing the overall quality of digital displays.

### BRIEF DESCRIPTION OF THE DRAWINGS

Non-limiting and non-exhaustive embodiments of the present technology are described below with reference to the following figures, in which like or similar reference numbers are used to refer to like or similar components throughout unless otherwise specified.

FIG. 1 is a partially schematic diagram of a digital display system configured in accordance with various embodiments of the present technology.

FIG. 2 is a partially schematic diagram of a display pixel array of the digital display system of FIG. 1.

FIG. 3 is a partially schematic diagram of a bit storage circuit configured in accordance with various embodiments of the present technology.

FIG. 4 is a partially schematic diagram of another bit storage circuit configured in accordance with various embodiments of the present technology.

FIG. 5 is an example timing diagram of a bit storage circuit in accordance with various embodiments of the present technology.

FIG. 6 is a graph illustrating voltage levels at an inverter output of the bit storage circuit of FIG. 4 in an unselected row in accordance with various embodiments of the present technology.

FIG. 7 is a partially schematic diagram of yet another bit storage circuit configured in accordance with various embodiments of the present technology.

Skilled artisans will appreciate that elements in the figures are illustrated for simplicity and clarity and are not necessarily drawn to scale. For example, the dimensions of some of the elements in the figures may be exaggerated relative to other elements to aid in understanding of various aspects of the present technology. In addition, common but well-understood elements or methods that are useful or necessary in a commercially feasible embodiment are often not depicted in the figures, or described in detail below, to avoid unnecessarily obscuring the description of various aspects of the present technology.

### DETAILED DESCRIPTION

The present disclosure generally to bit storage devices and associated devices, systems, and methods. For example, several embodiments described herein are directed to fast, low-leakage SRAM cells for display pixels and/or digital display systems. As a specific example, several embodiments of the present technology are directed to SRAM cells that can reduce or minimize current leakage through transistors without compromising speed. Such cells can include a latch and a plurality of transistors that form both pull-down paths and pull-up paths. In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for case of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

It will be understood that, although the terms first, second, third, etc., may be used in the disclosure and claims to describe various elements, these elements should not be limited by these terms and should not be used to determine the process sequence or formation order of associated elements. Unless otherwise indicated, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### A. Overview

As discussed above, many digital display systems employ bit storage circuits (e.g., SRAM cells) to maintain an on status or an off status of individual pixels, ensuring a correct image or video frame is displayed. Although these digital display systems offer great image and video display capabilities, one of the limitations with such digital display systems is that normal bit storage circuits, particularly SRAM cells in modern high-resolution displays, are susceptible to leakage current. Leakage occurs when unintended current flows through transistors, even when the cell is not being actively accessed. This can lead to power inefficiency, as leakage increases power consumption, which is especially problematic in battery-operated devices like smartphones and tablets. As demands for higher display resolution and density increase, minimizing leakage in bit storage circuits/SRAM cells becomes critical for improving energy efficiency and extending battery life. Attempts to provide digital display systems with low leakage have, thus far, resulted in compromised solutions that fail to meet speed, size, and/or other design/performance requirements.

It is appreciated that bit storage circuits configured in accordance with various embodiments of the present technology address at least some of the issues discussed above. For example, a bit storage circuit (e.g., an SRAM cell) disclosed herein can include transistors that can selectively cut off (or weaken without fully cutting off) pull-up paths between a supply voltage and a latch, such as while writing the latch. Cutting off or weakening the pull-up paths while writing the latch can prevent or at least reduce the effects of old data stored to the latch contending with new data being written to the latch. In some embodiments, the bit storage circuit further includes diodes or transistors that can conduct current between the supply voltage and the latch to compensate for (or replace) current that leaks from the latch.

Thus, as will be shown and described in the various examples below, a bit storage circuit configured in accordance with various embodiments of the present technology can include a latch coupled between a supply voltage and ground, and first through fourth transistors. The latch can comprise a pair of cross-coupled inverters having first and second inverters. The first transistor can selectively couple the first inverter to the supply voltage based at least in part on a first control signal. The second transistor can selectively couple an input of the first inverter to ground based at least in part on a second control signal different from the first control signal. The third transistor can selectively couple the second inverter to the supply voltage based at least in part on the second control signal. The fourth transistor can selectively couple an input of the second inverter to ground based at least in part on the first control signal. In some embodiments, the bit storage circuit further includes one or more diodes and/or transistors that are coupled in parallel with the first transistor or the third transistor between the supply voltage and the first inverter or the second inverter.

The present technology is expected to offer several advantages. For example, bit storage circuits of the present technology are expected to prevent (or at least reduce the effects of) old data written to the latch contending with new data being written to the latch. As another example, during a write operation for a bit storage circuit of the present technology, a transistor coupled between a supply voltage and an inverter of the bit storage circuit can be selectively deactivated to cut off (or at least weaken) a pull-up path between the supply voltage and the inverter. Cutting off or weakening the pull-up path during write operations is expected to decrease power consumption of the bit storage circuit and/or increase the speed at which the bit storage circuit is written with data. Additionally, bit storage circuits of the present technology are expected to compensate for (or replace) leakage current from the unselected latches during write operations to prevent write disturb. For example, bit storage circuits of the present technology can include diodes or biased transistors conduct current between the supply voltage and the corresponding latch to compensate for current that leaks out of the latch.

### B. Selected Embodiments of a Bit Storage Circuits, and Associated Devices, Systems, and Methods

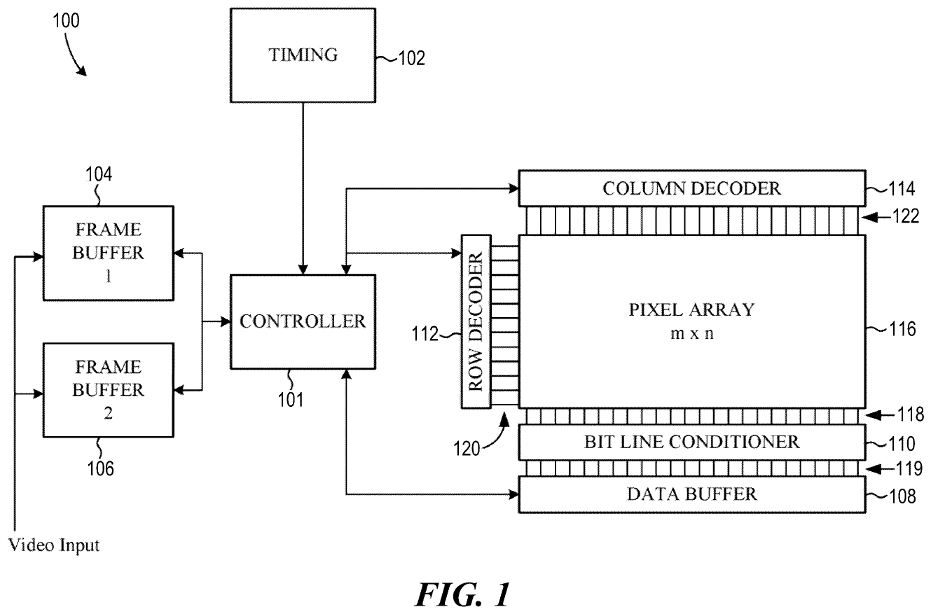

FIG. 1 is a partially schematic diagram of a digital display system 100 (“system 100”) configured in accordance with various embodiments of the present technology. The system 100 includes a controller 101, a timing generator 102, a first frame buffer 104, a second frame buffer 106, a data buffer 108, a bitline conditioner 110, a row decoder 112, a column decoder 114, and a display pixel array 116. It is appreciated that in other embodiments, the system 100 can omit one or more of the illustrated components and/or include additional components.

The controller 101 can be coupled to receive timing signals from the timing generator 102, and can be configured to use those timing signals to (a) coordinate the transfer of video data into the frame buffers 104 and 106, and (b) drive the pixels of the display pixel array 116 to display images corresponding to the video data. For example, the controller 101 can “set” (e.g., turn on) and “clear” (e.g., turn off or reset) each pixel of the display (e.g., so that each pixel is turned on for a portion of a predefined frame time). The amount of time that a particular pixel is turned on can be based on the value of a corresponding multi-bit intensity value stored in the frame buffer 104 or 106.

The first frame buffer 104 and the second frame buffer 106 can each be configured to receive an entire frame of video data and used by the controller 101 in an alternating manner. For example, while one frame of video data from the first frame buffer 104 is being used (e.g., by the controller 101) to determine the signals asserted on the display pixel array 116, a subsequent frame of video data can be loaded into the second frame buffer 106. Then, while the frame of video data from the second frame buffer 106 is being used (e.g., by the controller 101) to determine the signals asserted on the display pixel array 116, another subsequent frame of video data can be loaded into the first frame buffer 104, and so on.

In the illustrated embodiment, the display pixel array 116 is an m×n array of individual pixels, wherein m is the number of columns and n is the number of rows. The display pixel array 116 can display video (e.g., a rapid series of images) by turning the individual pixels on for predetermined portions of a frame period corresponding to particular desired intensities. The individual pixels can be turned on and off by latching data bits asserted on bitlines 118 by the bitline conditioner 110. The pixels can be configured to latch the data bits being asserted on the bitlines 118 by row enable signals from the row decoder 112 and column enable signals from the column decoder 114.

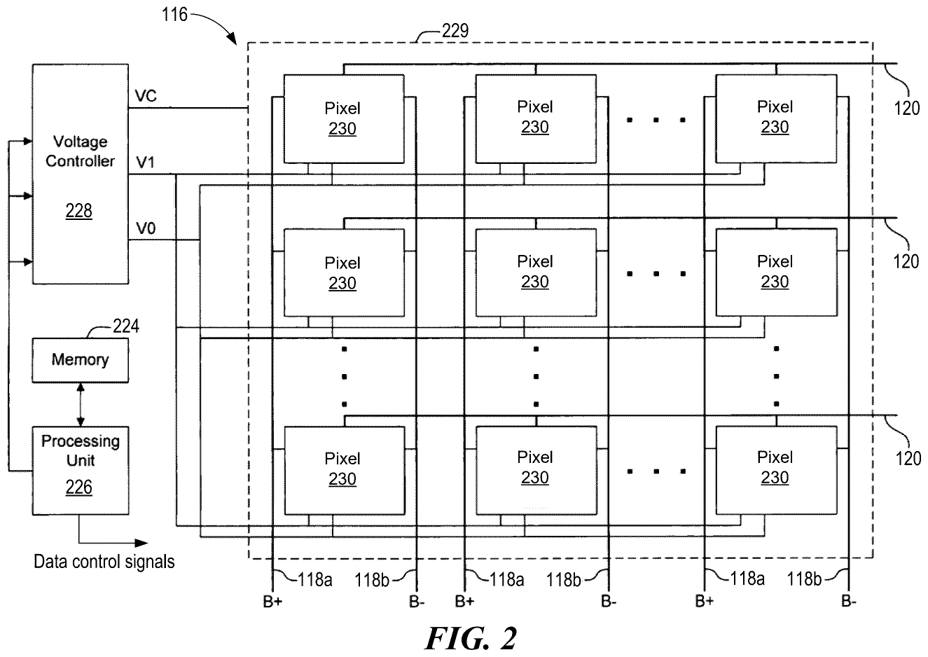

The data buffer 108 can be configured to receive lines of data bits that, in the illustrated example, turn individual pixels of the display pixel array 116 on and off. The bitline conditioner 110 can be configured to (a) receive, via data lines 119, data bits from the data buffer 108 in the form of low power electrical states and (b) assert more powerful signals onto the bitlines 118 and into the display pixel array 116, depending on the values of the original data bits. The internal circuitry and operation of the display pixel array 116 is described in further detail below with reference to FIGS. 2-7.

The row decoder 112 and the column decoder 114, responsive to addresses and control signals from the controller 101, can enable the pixels of the display pixel array 116 to latch data bits being asserted on the bitlines 118 by the data buffer 108 and the bitline conditioner 110. In order for a particular pixel to be enabled, it must be enabled by both the column decoder 114 and the row decoder 112.

The row decoder 112 can be coupled between the controller 101 and the display pixel array 116, and can be configured to selectively assert row enable signals onto wordlines 120 connected to the various pixel rows of the display pixel array 116. A row enable signal (also referred to herein as a “wordline select signal WL” or as a “write enable signal WL”) enables each pixel of a selected row to load a data bit being asserted on a corresponding bitline 118 by the data buffer 108. More specifically, the row decoder 112 can receive a series of row addresses from the controller 101, and can sequentially assert a row enable signal on a respective wordline 120 corresponding to each received row address.

The column decoder 114 can be coupled between the controller 101 and the display pixel array 116, and can be configured to, in response to control signals from the controller 101, selectively assert column enable signals (also referred to herein as “set control signal S” and “clear control signal C”) onto various pixel column lines 122 of the display pixel array 116. In some embodiments, the row decoder 112 can asserts a row enable signal on one wordline 120 at a time, and the column decoder 114 can simultaneously assert control signals on some, all, or none of the pixel column lines 122. Not asserting a column enable signal on a particular pixel column line 122 can allow an associated pixel of an enabled row to hold its prior data, notwithstanding the row enable signal being asserted on its wordline 120 by the row decoder 112.

FIG. 2 is a partially schematic diagram of the display pixel array 116 of the system 100 of FIG. 1. As shown, the display pixel array 116 includes a plurality of pixel cells 230 (also referred to herein as “pixels 230” or “pixel circuits 230”) arranged in columns and rows, a common transparent electrode 229 that overlays the entire array 116 of the pixels 230, a memory device 224, a processing unit 226 and a voltage controller 228. The memory device 224, the processing unit 226, and/or the voltage controller 228 can be disposed on or off chip with respect to the array 116 of pixels 230. It is appreciated that in other embodiments, the display pixel array 116 can omit one or more of the illustrated components and/or include additional components.

In the illustrated embodiment, each of the pixels 230 is coupled to (i) a first supply voltage V0 in the voltage controller 228, (ii) a second supply voltage V1 in the voltage controller 228, (iii) a corresponding one of first bitlines B+ 118a, (iv) a corresponding one of second bitlines B− 118b, and (v) a corresponding one of the wordlines 120. As shown, the pixels 230 of a same column can be coupled to a same one of the first bitlines B+ 118a and a same one of the second bitlines B− 118b, and the pixels 230 of a same row can be coupled to a same one of the wordlines 120. In some embodiments, the pixels 230 are formed in an integrated monolithic silicon backplane, overlaid with a plurality of pixel mirrors. A layer of liquid crystal material can be interposed between the pixel mirrors and the common transparent electrode 229. The common transparent electrode 229 can be composed of Indium-Tin-Oxide and/or other suitable material, and can be coupled to a common supply voltage VC in the voltage controller 228.

As discussed in further detail herein, each of the pixels 230 can include a bit storage circuit (e.g., including an SRAM cell or another type of memory element) that stores a single bit of information representing an on (e.g., active) state or an off (e.g., inactive) state of the pixel 230. The stored bits directly influence the brightness, color, and/or transparency of the pixels 230. By maintaining the pixel state even when not actively accessed, the bit storage circuit can ensure stable and continuous image rendering.

The memory device 224 can include a computer-readable medium (e.g., RAM, ROM, etc.) having code or instructions (e.g., data and commands) embodied therein for causing the processing unit 226 to implement the various methods and driving schemes described herein. The processing unit 226 can (i) receive the instructions from the memory device 224 (e.g., via a memory bus), (ii) provide internal voltage control signals to the voltage controller 228 (e.g., via a voltage control bus), and (iii) provide data control signals to the pixels 230 (e.g., via a data control bus).

In operation, rows of data bits can be asserted on the first bitlines B+ 118a and the second bitlines B− 118b, and assertion of a write enable signal on the wordline 120 of a particular row can cause the asserted bits to be written into the pixels 230 in that row. In this manner, data bits can be sequentially written to each pixel 230 of the entire display. Responsive to control signals received from the processing unit 226, the voltage controller 228 can provide predetermined or variable voltages to the pixels 230 via the first supply voltage V0 and the second supply voltage V1. The voltage controller 228 can also assert predetermined voltages on the common electrode 229 via the common supply voltage VC. The processing unit 226 can provide control signals to the voltage controller 228 and/or directly to the pixels 230. For example, the processing unit 226 can provide set, clear, and/or other control signals to transistors included in the bit storage circuits of the pixels 230.

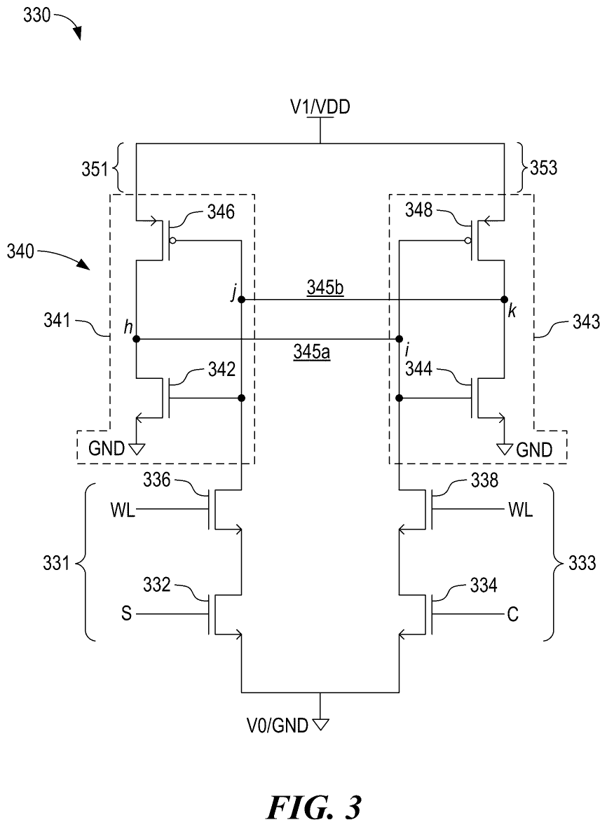

FIG. 3 is a partially schematic diagram of a bit storage circuit 330 configured in accordance with various embodiments of the present technology. It is appreciated that the bit storage circuit 330 can be an example of a bit storage circuit included in each of the pixels 230 of FIG. 2 and/or in other pixels configured in accordance with various embodiments of the present technology. In some embodiments, the bit storage circuit 330 can include an SRAM cell. For example, the bit storage circuit 330 can include a latch 340 coupled between the first supply voltage V1 (hereinafter referred to as “VDD” for the sake of example and clarity) and the second supply voltage V0 (hereinafter referred to as “ground” for the sake of example and clarity). The bit storage circuit 330 can further include a first pull-down leg 331 coupled between the latch 340 and ground, a second pull-down leg 333 coupled between the latch 340 and ground, a first pull-up leg 351 coupled between VDD and the latch 340, and a second pull-up leg 353 coupled between VDD and the latch 340.

In the illustrated embodiment, the latch 340 comprises a pair of cross-coupled inverters. The pair of cross-coupled inverters includes a first inverter 341 and a second inverter 343. The first inverter 341 includes a transistor 342, a transistor 346, an input j and an output h. In addition, the second inverter 343 includes a transistor 344, a transistor 348, an input i, and an output k.

Referring to the first inverter 341, the transistor 342 has a source coupled to ground, a drain coupled to the output h and to a drain of the transistor 346, and a gate coupled to the input j and to a gate of the transistor 346. In addition, the transistor 346 includes a source coupled to VDD. In some embodiments, the transistor 342 is an NMOS transistor, and the transistor 346 is a PMOS transistor.

Referring now to the second inverter 343, the transistor 344 has a source coupled to ground, a drain coupled to the output k and to a drain of the transistor 348, and a gate coupled to the input i and to a gate of the transistor 348. In addition, the transistor 348 includes a source coupled to VDD. In some embodiments, the transistor 344 is an NMOS transistor, and the transistor 348 is a PMOS transistor. Furthermore, the input i of the second inverter 343 can be coupled to the output h of the first inverter 341 at a first latch node 345a (“the first node 345a”), and the output k of the second inverter 343 can be coupled to the input j of the first inverter 341 at a second latch node 345b (“the second node 345b”).

The first pull-down leg 331 of the bit storage circuit 330 can include a transistor 332 and a transistor 336. In the illustrated embodiment, the transistor 332 includes a source coupled to ground, a drain coupled to a source of the transistor 336, and a gate coupled to receive a set control signal S (e.g., from one of the first bitlines B+ 118a of FIGS. 1 and 2) such that the transistor 332 can selectively couple the transistor 336 to ground based at least in part on a state of the control signal S. In addition, the transistor 336 includes a drain coupled to the input j of the first inverter 341, the gates of the transistors 342, 346 of the first inverter 341, and the output k of the second inverter 343. The transistor 336 further includes a gate coupled to receive a row enable signal WL such that the transistor 336 can selectively couple the input j of the first inverter 341 to the transistor 332 and/or ground (via the transistor 332) based at least in part on a state of the row enable signal WL. In some embodiments, the transistors 332, 336 can be NMOS transistors.

The second pull-down leg 333 of the bit storage circuit 330 is similar to the first pull-down leg 331. For example, the second pull-down leg 333 can include a transistor 334 and a transistor 338. In the illustrated embodiment, the transistor 334 includes a source coupled to ground, a drain coupled to a source of the transistor 338, and a gate coupled to receive a clear control signal C (e.g., from one of the second bitlines B− 118b of FIGS. 1 and 2) such that the transistor 334 can selectively couple the transistor 338 to ground based at least in part on a state of the control signal C. In addition, the transistor 338 includes a drain coupled to the input i of the second inverter 343, the gates of the transistors 344, 348 of the second inverter 343, and the output h of the first inverter 341. The transistor 338 further includes a gate coupled to receive the row enable signal WL such that the transistor 338 can selectively couple the input i of the second inverter 343 to the transistor 334 and/or ground (via the transistor 334) based at least in part on a state of the row enable signal WL (e.g., received at the gate terminal of the transistor 338). In some embodiments, the transistors 334, 338 can be NMOS transistors.

In operation, the control signals S and C and the row enable signal WL can be controlled to write data bits to the bit storage circuit 330. For example, to set a data bit of “1” onto the first node 345a, the write enable signal WL and the control signal S can be asserted to activate the transistors 336, 338 and the transistor 332, respectively. It is appreciated that only one of the control signals S or C may asserted at any given time. Thus, when the control signal S is asserted, the control signal C can be unasserted such that the transistor 334 is deactivated. As a result of the transistors 332, 336 being activated, the input j of the first inverter 341 can be coupled to ground via the first pull-down leg 331. In turn, the low voltage level of ground can deactivate the transistor 342 (e.g., an NMOS transistor) and can activate the transistor 346 (e.g., a PMOS transistor). The activated transistor 346 can thus couple the output h of the first inverter 341 to VDD, thereby pulling the first node 345a and the input i of the second inverter 343 toward the high voltage level of VDD using the first pull-up leg 351. As the input i is pulled high, the transistor 344 (e.g., an NMOS transistor) of the second inverter 343 can be activated and the transistor 348 (e.g., a PMOS transistor) of the second inverter 343 can be deactivated. The activated transistor 344 can couple the output k of the second inverter 343 to ground, thereby pulling the second node 345b and the input j of the first inverter 341 down toward the low voltage level of ground. In this manner, the latch 340 of the bit storage circuit 330 can be written such that a voltage at the first node 345a is in a first state (e.g., a high voltage state, or “1”) and a voltage at the second node 345b is in a second state (e.g., a low voltage state, or “0”).

The bit storage circuit 330 can be operated in a similar manner to set a data bit of “0” onto the first node 345a (e.g., to reset or clear the latch 340). More specifically, the write enable signal WL and the control signal C can be asserted to activate the transistors 336, 338 and the transistor 334, respectively. As discussed above, in some embodiments, only one of the control signals S or C may asserted at any given time. Thus, when the control signal C is asserted, the control signal S can be unasserted such that the transistor 332 is deactivated. As a result of the transistors 334, 338 being activated, the input i of the second inverter 343 can be coupled to ground via the second pull-down leg 333. In turn, the low voltage level of ground can deactivate the transistor 344 (e.g., an NMOS transistor) and can activate the transistor 348 (e.g., a PMOS transistor). The activated transistor 348 can thus couple the output k of the second inverter 343 to VDD, thereby pulling the second node 345b and the input j of the first inverter 341 toward the high voltage level of VDD using the second pull-up leg 353. As the input j is pulled high, the transistor 342 (e.g., an NMOS transistor) of the first inverter 341 can be activated and the transistor 346 (e.g., a PMOS transistor) of the first inverter 341 can be deactivated. The activated transistor 342 can couple the output h of the first inverter 341 to ground, thereby pulling the first node 345a and the input i of the second inverter 343 down toward the low voltage level of ground. In this manner, the latch 340 of the bit storage circuit 330 can be written (e.g., reset or cleared) such that a voltage at the first node 345a is in the second state (e.g., a low voltage state, or “0”) and a voltage at the second node 345b is in the first state (e.g., a high voltage state, or “1”).

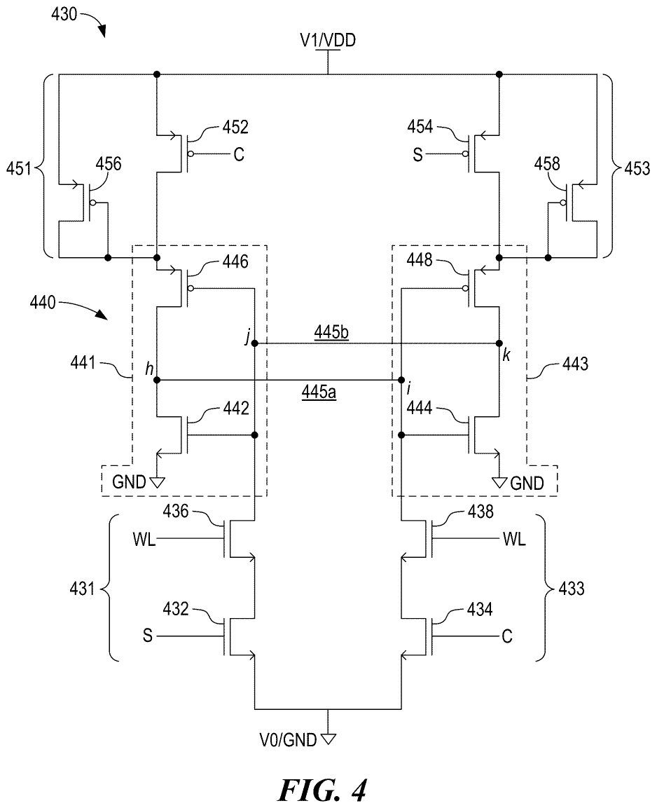

FIG. 4 is a partially schematic diagram of another bit storage circuit 430 configured in accordance with various embodiments of the present technology. It is appreciated that the bit storage circuit 430 can be an example of a bit storage circuit included in each of the pixels 230 of FIG. 2 and/or of other bit storage circuits configured in accordance with various embodiments of the present technology. In some embodiments, the bit storage circuit 430 can include an SRAM cell. For example, the bit storage circuit 430 can include a latch 440 coupled between VDD and ground, first and second pull-down legs 431, 433 coupled between the latch 440 and ground, and first and second pull-up legs 451, 453 coupled between VDD and the latch 440.

As shown, the latch 440, the first pull-down leg 431, and the second pull-down leg 433 can be identical (or at least generally similar) in structure and/or function to the latch 340, the first pull-down leg 331, and the second pull-down leg 333, respectively, of the bit storage circuit 330 of FIG. 3 described above. For example, the latch 440 includes a pair of cross-coupled inverters. The pair of inverters includes a first inverter 441 having transistors 442, 446 whose drains are coupled to one another, and a second inverter 443 having transistors 444, 448 whose drains are coupled to one another. The sources of the transistors 442, 444 can be coupled to ground. The first pull-down leg 431 includes transistors 432, 436, and the second pull-down leg 433 includes transistors 434, 438.

In some embodiments, the transistors 442, 446, 444, 448 of the latch 440, the first pull-down leg 431, and/or the second pull-down leg 433 can include low-leakage transistors (e.g., low-leakage high-threshold-voltage transistors (LLHVT), ultra-high-threshold-voltage transistors (UHVT)). However, low-leakage transistors are typically associated with longer lengths and slower operation times compared to other types of transistors. Thus, in some embodiments, the transistors 442, 446, 444, and/or 448 of the latch 440, the first pull-down leg 431, and/or the second pull-down leg 433 do not comprise low-leakage transistors so that these transistors can satisfy size, speed, and/or other constraints of the bit storage circuit 430.

Unlike the bit storage circuit 330 of FIG. 3, the first pull-up leg 451 of the bit storage circuit 430 of FIG. 4 includes (i) a transistor 452 selectively coupling the first inverter 441 (more specifically, the source of the transistor 446) to VDD based at least in part on a state of the control signal C applied to a gate of the transistor 452, and (ii) a diode 456. In the illustrated embodiment, the diode 456 is a transistor having a gate that is coupled to its drain. The transistor 452 and the diode 456 can be coupled in parallel between VDD and the first inverter 441 (more specifically, to the source of the transistor 446). Similarly, the second pull-up leg 453 of the bit storage circuit 430 includes (i) a transistor 454 selectively coupling the second inverter 443 (more specifically, the transistor 448) to VDD based at least in part on the control signal S applied to a gate of the transistor 454, and (ii) a diode 458. In the illustrated embodiment, the diode 458 is a transistor having a gate coupled to its drain. The transistor 454 and the diode 458 can be coupled in parallel between VDD and the second inverter 443 (more specifically, the source of the transistor 448). As shown, the transistors 452 can be activated when the transistor 434 is deactivated (e.g., based at least in part on a state of the control signal C), and the transistor 454 can be activated when the transistor 432 is deactivated (e.g., based at least in part on a state of the control signal S).

In some embodiments, the transistor 452, the transistor 454, the diode 456, and/or the diode 458 include a PMOS transistor. In some embodiments, the diode 456 and/or the diode 458 includes a high-leakage transistor or a low-threshold transistor (e.g., LLHVT, UHVT). In these and other embodiments, the diodes 456 and/or 458 can be configured to conduct a larger amount of sub-threshold current than off current of other transistors (e.g. the transistor 442 and/or the transistor 444) of the bit storage circuit 430. For example, the diode 456 and/or the diode 458 can include a transistor having a lower threshold voltage than the threshold voltages of one or more other transistors (e.g., the transistor 452 and/or the transistor 454) of the bit storage circuit 430. As another example, the diode 456 and/or the diode 458 can include a transistor having a smaller length than one or more other transistors (e.g., the transistors 452 and/or the transistor 454) of the bit storage circuit 430.

The bit storage circuit 430 can operate in a manner generally similar to the bit storage circuit 330 of FIG. 3 with a few exceptions relating to the first pull-up leg 451 and the second pull-up leg 453. Referring momentarily back to FIG. 3 for the sake of example, when setting a data bit of “1” onto the first node 345a, the write enable signal and the control signal S can be asserted and the control signal C is can be unasserted to pull up the first node 345a toward VDD and pull down the second node 345b toward ground. Prior to the write operation, however, the voltage level on the first node 345a may have been at ground, thus activating the transistor 348 via the input i of the second inverter 343. Because the transistors of the latch 340 are activated by the voltage level of the first and second nodes 345a, 345b, there can be a delay in properly writing the asserted data bits. For example, when the control signal S is turned high, although the voltage level on the second node 345b may eventually settle to ground, the initially or previously activated transistor 348 may temporarily provide a pull-up path for the second node 345b, resulting in the voltage level at the second node 345b being pulled in opposite directions (at least temporarily): pulled up by the transistor 348 and pulled down by the transistors 332, 336. Similarly, when the clear signal C is asserted, the voltage level at the first node 345a can be pulled in opposite directions (at least temporarily): pulled up by the transistor 346 and pulled down by the transistors 334, 338. Therefore, the bit storage circuit 330 of FIG. 3 can be vulnerable to old data stored to the latch 340 contending with new data being written to the latch 340, which can lead to increased power consumption and/or slower access/write times.

Referring back to FIG. 4, the transistors 452, 454 of the bit storage circuit 430 are expected to address this issue. More specifically, when the latch 440 is being written to set a data bit of “1” onto the first node 445a, the write enable signal WL and the control signal S can be asserted and the control signal C can be unasserted. As a result, the input j of the first inverter 441 can be pulled down toward ground via the first pull-down leg 431. In addition, asserting the control signal S deactivates the transistor 454 (e.g., a PMOS transistor) in the second pull-up leg 453. As a result, the second pull-up leg 453 can be cut (or at least weakened) such that the transistor 448 of the second inverter 443 is not coupled to VDD via the transistor 454 and/or is coupled to VDD via (e.g., only) the diode 458. (In some embodiments, the pull-up path provided by the diodes 456, 458 can be minimal or negligible. In other embodiments, the diodes 456, 458 are omitted.) Thus, although the voltage level on the first node 445a immediately prior to the write (set) operation may have been low such that the transistor 448 (e.g., a PMOS transistor) is activated, the transistor 454 of the second pull-up leg 453 can be deactivated when the control signal S is asserted, meaning that the input j can be pulled down toward ground more quickly and/or easily (via the transistors 436, 432) because the pull-up on the output k toward VDD is cut off or weakened. Stated another way, cutting/weakening the second pull-up leg 453 during write (set) operations can reduce, minimize, and/or eliminate old data stored to the latch 440 contending with writing new data to the latch 440.

A similar process occurs when the latch 440 is being written to clear/reset the voltage on the first node 445a to a data bit of “0.” More specifically, the write enable signal WL and the control signal C can be asserted and the control signal S can be unasserted. As a result, the input i of the second inverter 443 can be pulled down toward ground via the second pull-down leg 433. In addition, asserting the control signal C deactivates the transistor 452 (e.g., a PMOS transistor) in the first pull-up leg 451. As a result, the first pull-up leg 451 can be cut (or at least weakened) such that the transistor 446 of the first inverter 441 is not coupled to VDD via the transistor 452 and/or is coupled to VDD via (e.g., only) the diode 456. (In some embodiments, the pull-up path provided by the diodes 456, 458 can be minimal or negligible. In other embodiments, the diodes 456, 458 are omitted.) Thus, although the voltage level on the second node 445b immediately prior to the write (reset/clear) operation may have be low such that the transistor 446 (e.g., a PMOS transistor) is activated, the transistor 452 of the first pull-up leg 451 can be deactivated when the control signal C is asserted, meaning that the input i of the second inverter 443 can be pulled down toward ground more quickly and/or easily (via the transistors 438, 434) because the pull-up on the output h of the first inverter 441 toward VDD is cut off or weakened. Stated another way, cutting/weakening the first pull-up leg 451 during write (clear/reset) operations can reduce, minimize, and/or eliminate old data stored to the latch 440 contending with writing (resetting/clearing) new data to the latch 440.

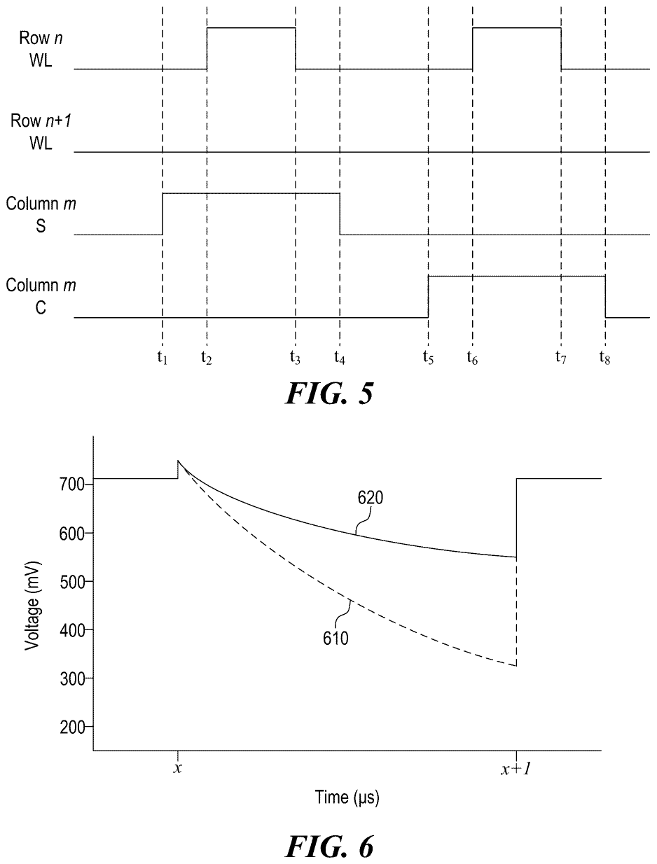

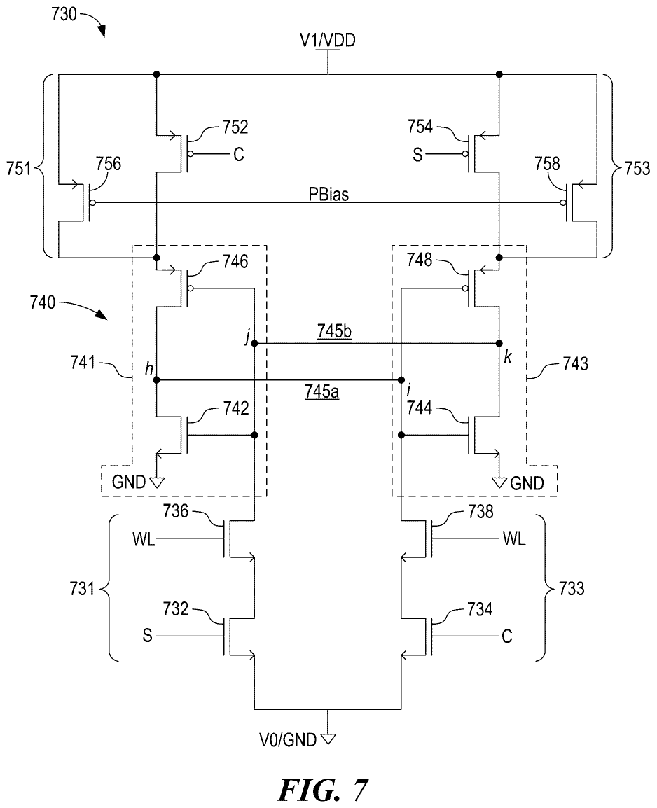

FIG. 5 is an example timing diagram for controlling a bit storage circuit in accordance with various embodiments of the present technology. The timing diagram of FIG. 5 can be an example timing diagram for the bit storage circuit 330 of FIG. 3, the bit storage circuit 430 of FIG. 4, the bit storage circuit of FIG. 7, and/or other bit storage circuits configured in accordance with various embodiments of the present technology. The illustrated timing diagram graphs during, for example, a write operation and a clear/reset operation for row n, the write enable signal WL of row n, the write enable signal WL of a neighboring row (row n+1), the control signal S on column m, and the control signal C on column m. As discussed in further detail herein, the timing diagram of FIG. 5 can illustrate a method for writing and/or clearing a latch (e.g., the latch 440) of a bit storage circuit (e.g., the bit storage circuit 430).

A method for writing the latch is shown between time t₁ and time t₄ in the illustrated embodiment. As illustrated, the control signal C for column m and the write enable signal WL for row n+1 remain unasserted for the entire duration of time between time t₁ and time t₄. Furthermore, at time t₁, the control signal S can be asserted for column m. As previously mentioned, the control signal S may be shared by the entire column m. As such, the control signal S may be asserted in a plurality of bit storage circuits that are arranged in the same column m but that are each positioned in different rows from one another. Asserting the control signal S may include activating one or more transistors of one or more pull-down legs of the bit storage circuit.

Writing the latch can further include, at time t₁, cutting or weakening a pull-up leg (e.g., the second pull-up leg 453 of FIG. 4) of the bit storage circuit. In some embodiments, cutting or weakening the pull-up leg of the bit storage circuit includes applying the asserted control signal S to a gate of a transistor (e.g., the transistor 454) in the pull-up leg of the bit storage circuit (e.g., such that the transistor is deactivated).

At time t₂, the write enable signal WL can be asserted for row n. Referring to FIG. 4 for the sake of example, asserting the write enable signal WL when the control signal S is also asserted can selectively couple an input of a first inverter (e.g., the input j of the first inverter 441) and an output of a second inverter (e.g., the output k of the second inverter 443) of the latch to a first voltage (e.g., ground) such that the input of the first inverter and the output of the second inverter are pulled down toward the first voltage.

In some embodiments, writing the latch further includes, at or after time t₂, selectively coupling an output (e.g., the output h) of the first inverter and an input (e.g., the input i) of the second inverter of the latch to a second voltage (e.g., VDD) such that an output of the first inverter and an input of the second inverter are pulled up toward a second voltage greater than the first voltage.

At time t₃, the write enable signal WL can be de-asserted for row n. De-asserting the write enable signal WL can include selectively uncoupling the input of the first inverter and the output of the second inverter from the first voltage.

At time t₄, the control signal S can be de-asserted for column m. De-asserting the control signal S can reactivate a transistor in a pull-up leg of the bit storage circuit. Additionally, or alternatively, de-asserting the control signal S can deactivate one or more transistors in one or more pull-down legs of the bit storage circuit.

Although the write enable signal WL is shown in FIG. 5 as being (a) asserted after asserting the control signal S and (b) de-asserted before de-asserting the control signal S, the present technology is not so limited. For example, the write enable signal WL can be asserted before or at a same time as asserting the control signal S in other embodiments of the present technology. As another example, the write enable signal WL can be de-asserted after or at a same time as de-asserting the control signal S in other embodiments of the present technology.

Resetting or clearing the latch is shown between time t₅ and time t₈ in the illustrated embodiment. As illustrated, the control signal S for column m and the write enable signal WL for row n+1 remain unasserted for the entire duration of time between time t₅ and time t₈. Furthermore, at time t₅, the control signal C can be asserted for column m. As previously mentioned, the control signal C may be shared by the entire column m. As such, the control signal C may be asserted in a plurality of bit storage circuits that are arranged in the same column m but that are each positioned in different rows from one another. Asserting the control signal C may include activating one or more transistors in one or more pull-down legs of the bit storage circuit.

Clearing the latch can further include, at time t₅, cutting or weakening a pull-up leg (e.g., the first pull-up leg 451) of the bit storage circuit. In some embodiments, cutting or weakening the pull-up leg of the bit storage circuit includes applying the asserted control signal C to a gate of a transistor (e.g., the transistor 452) in the pull-up leg of the bit storage circuit (e.g., such that the transistor is deactivated).

At time t₆, the write enable signal WL can be asserted for row n. Referring to FIG. 4 for the sake of example, asserting the write enable signal WL when the control signal C is also asserted can selectively couple the input of the second inverter and the output of the first inverter to the first voltage (e.g., ground) such that the input of the second inverter and the output of the first inverter are pulled down toward the first voltage.

In some embodiments, clearing the latch further includes, at or after time t₆, selectively coupling the input of the first inverter and the output of the second inverter to the second voltage (e.g., VDD) such that the input of the first inverter and the output of the second inverter are pulled up toward the second voltage that is greater than the first voltage.

At time t₇, the write enable signal WL can be de-asserted for row n. De-asserting the write enable signal WL can include selectively uncoupling the input of the second inverter and the output of the first inverter from the first voltage.

At time t₈, the control signal C can be de-asserted for column m. De-asserting the control signal C can reactivate a transistor in a pull-up leg of the bit storage device. Additionally, or alternatively, de-asserting the control signal C can deactivate one or more transistors in one or more pull-down legs of the bit storage circuit.

As discussed above, the write enable signal WL for row n+1 can remain de-asserted during the write operation of row n and/or during the clear/reset operation of row n, effectively unselecting row n+1 for the write and clear/reset operations. Nevertheless, as previously mentioned, the control signals S and C may still be applied to a bit storage circuit in unselected row n+1 that is positioned within column m. As a result, one or more pull-up legs in the bit storage circuit of unselected row n+1 and column m may be cut or weakened during the write and clear/set operations for the bit storage circuit of row n and column n. Therefore, asserting the control signals S and/or C on the bit storage circuit of row n+1 and column n without asserting the write enable signal WL for row n+1 can cause write disturb issues on this bit storage circuit, especially as current leaks from transistors of the latch of this bit storage circuit. Diodes (e.g., the diodes 456, 458) in the pull-up legs of this bit storage circuit are expected to alleviate (e.g., reduce, minimize, and/or eliminate) the write disturb concern.

More specifically, FIG. 6 is a graph illustrating voltage levels at the output k of the second inverter 443 (FIG. 4) in an unselected row (e.g., the row n+1 of FIG. 5) in accordance with various embodiments of the present technology. Referring momentarily back to FIG. 4, during a write operation for a bit storage circuit in an adjacent row and the same column as the bit storage circuit 430, the second pull-up leg 453 can be cut/weakened via the assertion of the control signal S for that column. During this time, current may leak through the transistor 444 of the latch 440. Absent the diode 458 in the second pull-up leg 453, as current leaks from the latch 440 through the transistor 444, the current on the latch 440 would not be replenished via the transistor 448 because (although activated), the second pull-up leg 453 would be uncoupled from VDD while the transistor 454 is deactivated. As a result, the leakage current may compromise the integrity of the data stored in the bit storage circuit 430. For example, if the voltage on the second node 445b is initially high (e.g., “1”) at the start of the write operation, the leakage current from the transistor 444 can drop the voltage on the second node 445b toward a voltage that activates the transistor 446 and deactivates the transistor 442 of the first inverter 441. This is shown by plot 610 in FIG. 6. As the voltage on the second node 445b drop below threshold voltages of the transistors 446 and 442 of the first inverter 441, the voltage value on the first node 445a can be flipped from low (e.g., “0”) to high while the voltage value on the second node 445b can be flipped from high to low, thereby corrupting the data stored on the latch 440.

The presence of the diode 458 in the second pull-up leg 453, however, is expected to reduce, minimize, and/or eliminate this concern. More specifically, the diode 458 is expected to conduct an amount of sub-threshold current during the period of time that the transistor 454 is deactivated. As a result, current conducted through the diode 458 is expected to replenish the latch 440 with current via the transistor 448 to compensate for the current that leaks from the transistor 444, thereby stopping the voltage drop on the second node 445b. This is shown by plot 620 of FIG. 6. Therefore, the diodes 458 in the second pull-up leg 453 of the bit storage circuit 430 is expected to reduce, minimize, and/or eliminate the risk of write disturbance on the bit storage circuit 430 while writing other bit storage circuits of the same column. The diode 556 in the first pull-up leg 451 of the bit storage circuit 430 is expected to provide similar benefits during reset/clear operations of other bit storage circuits of the same column.

Returning to a discussion of the graph of FIG. 6 for the sake of completeness, the first plot 610 represents the voltage level at (i) the output h of the first inverter 441 of the bit storage circuit 430 (for reset/clear operations of other bit storage circuits of the same column) or (ii) the output k of the second inverter 443 (for write operations of other bit storage circuits of the same column), in embodiments of the bit storage circuit 430 that omit the diodes 456, 458. By contrast, the second plot 620 represents the voltage level at (i) the output h of the first inverter 441 (for reset/clear operations of other bit storage circuits of the same column) or (ii) the output k of the second inverter 443 (for write operations of other bit storage circuits of the same column), in embodiments of the bit storage circuit 430 that include the diodes 456, 458. As shown in FIG. 6, each of the plots 610 and 620 indicates that the corresponding latch node is initially storing (at or before time x) approximately 720 mV, which can correspond to a data bit of “1” in some embodiments. At time x, the control signal S or the control signal C is asserted (thereby cutting or weakening a pull-up leg of the bit storage circuit 430) while the write enable signal WL remains de-asserted. Thereafter, leakage current from the latch 440 causes the voltage level on the corresponding latch node to drop. As shown, both the voltage drop and the rate of voltage drop is significantly less for the second plot 620 (embodiments including the diodes 456, 458) than for the first plot 610 (embodiments omitting the diodes 456, 458). In some embodiments, the voltage drop exhibited by the first plot 610 may be enough to flip the state of the latch 440, causing data corruption. For plot 620, the amount of leaking from the latch 440 and the amount of current replenished into the latch 440 via the diode 456 and/or the diode 458 can equilibrate at a voltage level (e.g., approximately 550 mV in the illustrated embodiment) that does not flip the state of the latch 440. Additionally, or alternatively, the amount of current replenished into the latch 440 via the diode 456 and/or the diode 458 can prolong the amount of time the voltage takes to drop to levels that would flip the state of the latch 440. Such prolonging can ensure that the write or clear/reset operations for other bit storage circuits of the same column conclude before the voltage drops to a level that flips the latch 440.

FIG. 7 is a partially schematic diagram of another bit storage circuit 730 configured in accordance with various embodiments of the present technology. It is appreciated that the bit storage circuit 730 can be an example of a bit storage circuit included in each of the pixels 230 of FIG. 2, and/or of other bit storage circuits configured in accordance with various embodiments of the present technology. In some embodiments, the bit storage circuit 730 can include an SRAM cell. For example, the bit storage circuit 730 can include a latch 740 coupled between VDD and ground, first and second pull-down legs 731, 733 coupled between the latch 740 and ground, and first and second pull-up legs 751, 753 coupled between VDD and the latch 740.

As shown, the latch 740, the first pull-down leg 731, and the second pull-down leg 733 can be identical or generally similar in structure and/or function to the latch 440, the first pull-down leg 431, and the second pull-down leg 433, respectively, of the bit storage circuit 430 in FIG. 4. For example, the latch 740 includes a pair of cross-coupled inverters. The pair of inverters includes a first inverter 741 having transistors 742, 746 and a second inverter 743 having transistors 744, 748. The first pull-down leg 731 includes transistors 732, 736, and the second pull-down leg 733 includes transistors 734, 738.

In some embodiments, the transistors of the latch 740, the first pull-down leg 731, and/or the second pull-down leg 733 can include low-leakage transistors (e.g., low-leakage high-threshold-voltage transistors (LLHVT), ultra-high-threshold-voltage transistors (UHVT)). However, low-leakage transistors are typically associated with longer lengths and slower operation times compared to other types of transistors (e.g., conventional transistors). Thus, in some embodiments, the transistors 742, 746, 744, 748 of the latch 740, the first pull-down leg 731, and/or the second pull-down leg 733 do not comprise low-leakage transistors so that these transistors can satisfy size, speed, and/or other constraints of the bit storage circuit 730.

Like in the bit storage circuit 430 of FIG. 4, the first second pull-up leg 751 includes a transistor 752 (e.g., a PMOS transistor) selectively coupling the first inverter 741 to VDD based at least in part on a state of the control signal C applied to a gate of the transistor 752, and the second pull-up leg 753 includes a transistor 754 selectively coupling the second inverter 743 to VDD based at least in part on a state of the control signal S applied to a gate of the transistor 754. Unlike in the bit storage circuit 430 of FIG. 4, however, the first second pull-up leg 751 includes a transistor 756 having a gate coupled to receive a bias voltage PBias as opposed to a diode, and the second pull-up leg 753 includes a transistor 758 having a gate coupled to receive a bias voltage (e.g., bias voltage PBias or another bias voltage level). The transistors 756 couples the first inverter 743 (more specifically, the source of the transistor 746) to VDD, and the transistor 758 couples the second inverter 743 (more specifically, the source of the transistor 748) to VDD.

In operation, the bias voltage PBias applied to the gates of the transistors 756, 758 allows an amount of current to be conducted through the transistors 756, 758. The bias voltage PBias can be set at a level such that the amount of current conducted through the transistors 756,758 is at about 20 nA, which is greater than an amount of current that leaks from a corresponding one of the first and second inverters 741, 743. Therefore, similar to the diodes 456, 458 of FIG. 4, the transistors 756, 758 are expected to provide a solution to the leakage current/write disturb issues described above.

Thus, referring back to the method described above with reference to the timing diagram of FIG. 5, the method can further include, when (i) the write enable signal WL applied to the gates of corresponding transistors (e.g., the transistors 436, 438) is unasserted while (ii) the control signal S or the control signal Cis asserted, conducting a current between VDD and one of the first and second inverters via either (a) a diode (e.g., one of the diodes 456, 458) or (b) a transistor (e.g., one of the transistors 756, 758) having a gate coupled to receive a bias voltage. In some embodiments, conducting the current includes conducting an amount of current between VDD and the second inverter that is equal to or greater than an amount of current leaking from the latch.

### D. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. The phrases “about” or substantially” are to be interpreted as including values within ±10% of the provided value. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

1. A bit storage circuit, comprising:
a latch coupled between a supply voltage and ground, the latch comprising a pair of cross-coupled inverters having a first inverter and a second inverter;
a first transistor coupled between the first inverter and the supply voltage, the first transistor configured to selectively couple the first inverter to the supply voltage based at least in part on a first control signal;
a second transistor coupled between an input of the first inverter and ground, the second transistor configured to selectively couple the input of the first inverter to ground based at least in part on a second control signal different from the first control signal;
a third transistor coupled between the second inverter and the supply voltage, the third transistor configured to selectively couple the second inverter to the supply voltage based at least in part on the second control signal; and
a fourth transistor coupled between an input of the second inverter and ground, the fourth transistor configured to selectively couple the input of the second inverter to ground based at least in part on the first control signal.

2. The bit storage circuit of claim 1, further comprising a diode, wherein the diode and the first transistor are coupled in parallel between the first inverter and the supply voltage.

3. The bit storage circuit of claim 2, wherein the diode includes a PMOS transistor having (i) a source terminal, (ii) a drain terminal, and (iii) a gate coupled to the drain terminal.

4. The bit storage circuit of claim 2, wherein the diode includes a low-threshold or high-leakage transistor.

5. The bit storage circuit of claim 2, wherein the diode includes a transistor having a smaller length than the first transistor.

6. The bit storage circuit of claim 2, wherein the diode includes a transistor having a lower threshold voltage than a threshold voltage of the first transistor.

7. The bit storage circuit of claim 2, wherein the diode is a first diode, wherein the bit storage circuit further comprises a second diode, and wherein the second diode and the third transistor are coupled in parallel between the second inverter and the supply voltage.

8. The bit storage circuit of claim 1, further comprising a fifth transistor, wherein the fifth transistor and the first transistor are coupled in parallel between the first inverter and the supply voltage.

9. The bit storage circuit of claim 8, wherein the fifth transistor includes a gate coupled to receive a bias voltage.

10. The bit storage circuit of claim 9, wherein the fifth transistor is configured, upon receiving the bias voltage at the gate, to conduct a current between the supply voltage and the first inverter greater than a leakage current from the first inverter.

11. The bit storage circuit of claim 10, wherein the current is about 20 nA.

12. The bit storage circuit of claim 8, further comprising a sixth transistor, wherein the sixth transistor and the third transistor are coupled in parallel between the second inverter and the supply voltage, and wherein the sixth transistor includes a gate coupled to receive a bias voltage.

13. The bit storage circuit of claim 1, wherein:
the first inverter includes a fifth transistor and a sixth transistor;
the fifth transistor includes a source coupled to the first transistor and either (a) a diode or (b) a transistor having a gate coupled to receive a bias voltage, a gate coupled to the input of the first inverter, and a drain coupled to an output of the first inverter;
the diode or the transistor are coupled in parallel with the first transistor between the supply voltage and the first inverter; and
the sixth transistor includes a drain coupled to the drain of the fifth transistor and the output of the first inverter, a source coupled to ground, and a gate coupled to the input of the first inverter.

14. The bit storage circuit of claim 13, wherein:
the second inverter includes a seventh transistor and an eighth transistor;
the seventh transistor includes a source coupled to the third transistor and to either (a) another diode or (b) another transistor having a gate coupled to receive the bias voltage, a gate coupled to the input of the second inverter, and a drain coupled to an output of the second inverter;
the other diode or the other transistor are coupled in parallel with the third transistor between the supply voltage and the second inverter; and
the eighth transistor includes a drain coupled to the drain of the seventh transistor and the output of the second inverter, a source coupled to ground, and a gate coupled to the input of the second inverter.

15. The bit storage circuit of claim 1, further comprising a fifth transistor coupled between the second transistor and the input of the first inverter, the fifth transistor configured to selectively couple the second transistor to the input of the first inverter based at least in part on a third control signal different from the first and second control signals.

16. The bit storage circuit of claim 15, further comprising a sixth transistor coupled between the fourth transistor and the input of the second inverter, the sixth transistor configured to selectively couple the fourth transistor to the input of the second inverter based at least in part on the third control signal.

17. The bit storage circuit of claim 15, wherein the first control signal is a set control signal, the second control signal is a clear control signal, and the third control signal is a wordline select control signal.

18. The bit storage circuit of claim 1, wherein the bit storage circuit includes a static random-access memory (SRAM) cell.

19. A bit storage circuit, comprising:
a first inverter;
a second inverter having (i) an input coupled to an output of the first inverter, and (ii) an output coupled to an input of the first inverter;
a first transistor configured to selectively couple the first inverter to a supply voltage;
a second transistor configured to selectively couple the first inverter to ground;
a third transistor configured to selectively couple the first inverter to the second transistor;
a fourth transistor configured to selectively couple the second inverter to the supply voltage;
a fifth transistor configured to selectively couple the second inverter to ground; and
a sixth transistor configured to selectively couple the second inverter to the fifth transistor.

20. The bit storage circuit of claim 19, further comprising a diode, wherein the diode and the first transistor are coupled in parallel between the supply voltage and the first inverter.

21. The bit storage circuit of claim 20, wherein the diode is a first diode, wherein the bit storage circuit further comprises a second diode, and wherein the second diode and the fourth transistor are coupled in parallel between the supply voltage and the second inverter.

22. The bit storage circuit of claim 19, further comprising a seventh transistor, wherein the seventh transistor and the first transistor are coupled in parallel between the supply voltage and the first inverter, and wherein a gate of the seventh transistor is coupled to receive a bias voltage.

23. The bit storage circuit of claim 22, wherein the bias voltage is a first bias voltage, wherein the bit storage circuit further comprises an eighth transistor, wherein the eighth transistor and the fourth transistor are coupled in parallel between the supply voltage and the second inverter, and wherein a gate of the eighth transistor is coupled to receive a second bias voltage.

24. The bit storage circuit of claim 19, wherein the first transistor and the fifth transistor are configured such that first and fifth transistors are activated and deactivated together.

25. The bit storage circuit of claim 24, wherein the second transistor and the fourth transistor are configured such that the second and fourth transistors are activated and deactivated together.

26. The bit storage circuit of claim 19, wherein a gate the first transistor and/or a gate of the fifth transistor is/are coupled to receive a first control signal, and wherein a gate of the second transistor and/or a gate of the fourth transistor is/are coupled to receive a second control signal different from the first control signal.

27. A method, comprising:
writing a latch of a bit storage circuit, wherein writing the latch includes—
selectively coupling an input of a first inverter of the latch and an output of a second inverter of the latch to ground such that the input of the first inverter and the output of the second inverter are pulled down toward a first voltage, and
at least while the input of the first inverter is selectively coupled to ground, cutting or weakening a pull-up leg of the second inverter, wherein the pull-up leg of the second inverter extends between a supply voltage and the second inverter.

28. The method of claim 27, wherein writing the latch further includes, at least while the input of the first inverter and the output of the second inverter are selectively coupled to ground, selectively coupling an output of the first inverter and an input of the second inverter to the supply voltage such that the output of the first inverter and the input of the second inverter are pulled up toward a second voltage greater than the first voltage.

29. The method of claim 27, wherein selectively coupling the input of the first inverter and the output of the second inverter to ground includes (i) asserting a first control signal applied to a gate of a first transistor of the bit storage circuit and (ii) asserting a write enable signal applied to a gate of a second transistor of the bit storage circuit, wherein the first transistor and the second transistor are coupled in series between the input of the first inverter and ground.

30. The method of claim 29, wherein cutting or weakening the pull-up leg of the second inverter includes asserting the first control signal applied to a gate of a third transistor of the bit storage circuit, wherein the third transistor is coupled in series between the supply voltage and the second inverter.

31. The method of claim 29, further comprising, when (i) the write enable signal applied to the gate of the second transistor is not enabled and (ii) the second inverter is not selectively coupled to the supply voltage via the pull-up leg of the second inverter, conducting a current between the supply voltage and the second inverter via either a diode or a transistor having a gate coupled to receive a bias voltage.

32. The method of claim 31, wherein conducting the current includes conducting an amount of current between the supply voltage and the second inverter that is greater than an amount of leakage current escaping the second inverter.
